(19) United States
(12) Patent Application Publication
(10) Pub. No.: US 2024/0317574 A1
(43) Pub. Date: Sep. 26, 2024

(54) MEMS DEVICE AND METHOD OF MANUFACTURING MEMS DEVICE

(71) Applicant: ROHM CO., LTD., Kyoto (JP)

(72) Inventors: Martin Wilfried HELLER, Kyoto (JP); Hiroki MIYABUCHI, Kyoto (JP)

(73) Assignee: ROHM CO., LTD., Kyoto (JP)

(21) Appl. No.: 18/613,801

(22) Filed: Mar. 22, 2024

(30) Foreign Application Priority Data
Mar. 24, 2023 (JP) 2023-048742

(51) Int. Cl. B81B 3/00; B81C 1/00; G01P 15/125

(52) U.S. Cl. CPC B81B 3/0008; B81C 1/00626; G01P 15/125; B81B 2201/0235; B81B 2203/0118; B81B 2203/04

(57) ABSTRACT

A MEMS device includes: a substrate including a silicon layer; an isolation joint configured to divide the substrate into a first portion including an insulating layer formed on the silicon layer and a second portion including the silicon layer in a plan view, and configured to electrically insulate the first portion and the second portion while mechanically connecting the first portion and the second portion; and a wiring layer arranged on the substrate.

### CROSS-REFERENCE TO RELATED APPLICATION

This application is based upon and claims the benefit of priority from Japanese Patent Application No. 2023-048742, filed on Mar. 24, 2023, the entire contents of which are incorporated herein by reference.

### TECHNICAL FIELD

The present disclosure relates to a micro electro mechanical system (MEMS) device and a method of manufacturing a MEMS device.

### BACKGROUND

In the related art, an acceleration sensor, which includes a substrate, a movable portion connected to the substrate via an insulating region, and wiring electrodes arranged on the substrate and the movable portion via an upper insulating film, is known. The wiring electrodes are made of aluminum. The wiring electrodes are insulated from the substrate by the upper insulating film, and are electrically connected to the movable portion through a via (electrical connection) provided in the upper insulating film.

### BRIEF DESCRIPTION OF DRAWINGS

The accompanying drawings, which are incorporated in and constitute a part of the specification, illustrate embodiments of the present disclosure.

FIG. 1 is a plan view of an acceleration sensor according to an embodiment of the present disclosure.

FIG. 2 is an enlarged perspective view of a vicinity of region A of the acceleration sensor shown in FIG. 1.

FIG. 3 is an enlarged view of region A of the acceleration sensor shown in FIG. 1.

FIG. 4 is a cross-sectional view taken along line IV-IV in FIG. 3.

FIG. 5 is a flowchart for explaining a manufacturing process of the acceleration sensor according to an embodiment of the present disclosure.

FIG. 6 is a diagram for explaining the manufacturing process of the acceleration sensor according to an embodiment of the present disclosure.

FIG. 7 is a diagram for explaining the manufacturing process of the acceleration sensor according to an embodiment of the present disclosure.

FIG. 8 is a diagram for explaining the manufacturing process of the acceleration sensor according to an embodiment of the present disclosure.

FIG. 9 is a diagram for explaining the manufacturing process of the acceleration sensor according to an embodiment of the present disclosure.

FIG. 10 is a diagram for explaining the manufacturing process of the acceleration sensor according to an embodiment of the present disclosure.

FIG. 11 is a diagram for explaining the manufacturing process of the acceleration sensor according to an embodiment of the present disclosure.

FIG. 12 is a diagram for explaining the manufacturing process of the acceleration sensor according to an embodiment of the present disclosure.

FIG. 13 is a diagram for explaining the manufacturing process of the acceleration sensor according to an embodiment of the present disclosure.

FIG. 14 is a diagram for explaining the manufacturing process of the acceleration sensor according to an embodiment of the present disclosure.

FIG. 15 is a diagram for explaining the manufacturing process of the acceleration sensor according to an embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, a MEMS device and a method of manufacturing a MEMS device according to one embodiment of the present disclosure will be described with reference to the accompanying drawings. In essence, the following description is merely an example, and is not intended to limit the present disclosure, its applications, or its uses. Further, the drawings are schematic, and the ratio of respective dimensions is different from the actual one.

### [Acceleration Sensor]

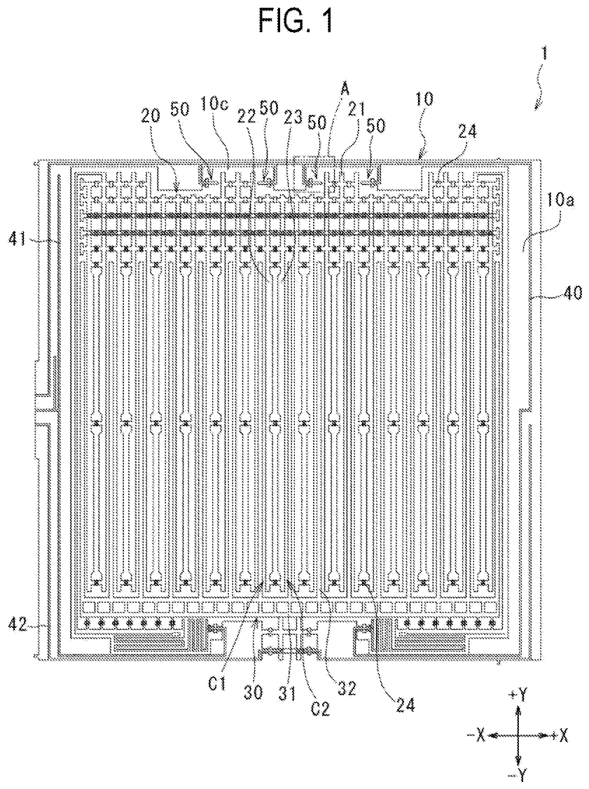

FIG. 1 is a plan view schematically showing an acceleration sensor 1 according to an embodiment of the present disclosure. The acceleration sensor 1 according to the present embodiment is a capacitive acceleration sensor manufactured using a semiconductor microfabrication technique. The acceleration sensor 1 according to the present embodiment is an example of a MEMS device according to the present disclosure.

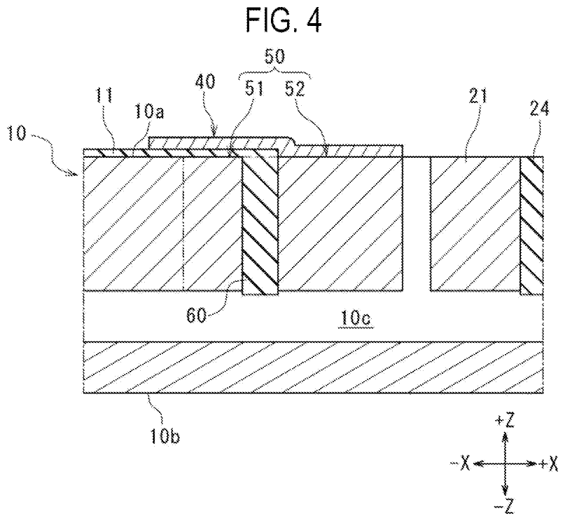

In the following description, for the sake of convenience, among the directions extending along the respective sides of the acceleration sensor 1 in the plan view shown in FIG. 1, a left-right direction in FIG. 1 will be referred to as an X direction, and an up-down direction in FIG. 1 will be referred to as a Y direction. In the cross-sectional view shown in FIG. 4, a thickness direction of the acceleration sensor 1 (up-down direction in FIG. 4) will be referred to as a Z direction. In particular, in FIG. 1, the right side may be referred to as +X direction, the left side as −X direction, the upper side as +Y direction, and the lower side as −Y direction. In FIG. 4, the upper side may be referred to as +Z direction, and the lower side may be referred to as −Z direction. In the present embodiment, the X direction, Y direction, and Z direction are orthogonal to each other.

As shown in FIG. 1, the acceleration sensor 1 includes a substrate 10, and a movable electrode 20 and a fixed electrode 30 which are provided within the substrate 10. The acceleration sensor 1 includes a plurality of electrode pads (not shown) through which electrical signals (voltages) are inputted and outputted between the movable electrode 20 and the fixed electrode 30.

The substrate 10 has a rectangular shape in a plan view. The substrate 10 has a first main surface 10a located on the +Z side and a second main surface 10b (see FIG. 4) located on the −Z side and opposite to the first main surface 10a. The first main surface 10a and the second main surface 10b extend parallel to the X direction and the Y direction. The substrate 10 has a cavity 10c recessed from the first main surface 10a toward the −Z side and having a rectangular shape in a plan view.

The movable electrode 20 and the fixed electrode 30 constitute MEMS electrodes. The movable electrode 20 and the fixed electrode 30 are arranged within the cavity 10c.

The movable electrode 20 is spaced apart from the bottom surface of the cavity 10c toward the +Z side. The movable electrode 20 is connected to the substrate 10 so as to be movable relative to the substrate 10. The movable electrode 20 includes a movable electrode base 21 that functions as a proof mass of the acceleration sensor 1, a first movable electrode finger 22 extending in the Y direction, and a second movable electrode finger 23 located on the +X side of the first movable electrode finger 22 and extending in the Y direction. The +Y side end of the first movable electrode finger 22 is connected to the movable electrode base 21. The +Y side end of the second movable electrode finger 23 is connected to the movable electrode base 21.

The movable electrode 20 includes a movable electrode isolation joint 24 for electrically insulating the first movable electrode finger 22 and the second movable electrode finger 23 while mechanically connecting them in the X direction. The movable electrode isolation joint 24 of the present embodiment is silicon oxide (SiO₂) formed by thermally oxidizing the substrate 10.

In the present embodiment, the first movable electrode finger 22 and the second movable electrode finger 23 arranged adjacent to the +X side of the first movable electrode finger 22 constitute a pair of movable electrode fingers. In the movable electrode 20 of the present embodiment, a plurality of movable electrode finger pairs are provided. The plurality of movable electrode finger pairs are arranged side by side in the X direction.

The fixed electrode 30 is spaced apart from a bottom surface of the cavity 10c toward the +Z side. The fixed electrode 30 is fixed to the substrate 10. In other words, the fixed electrode 30 is connected to the substrate 10 so as not to move relative to the substrate 10. The fixed electrode 30 includes a fixed electrode base 31, and a plurality of fixed electrode fingers 32 extending in the Y direction and having-Y side ends connected to the fixed electrode base 31. The fixed electrode fingers 32 are arranged side by side in the X direction. A pair of movable electrode fingers is arranged between two fixed electrode fingers 32 arranged adjacent to each other in the X direction. In other words, the fixed electrode fingers 32 and the movable electrode finger pairs are arranged alternately along the X direction. The fixed electrode fingers 32 and the movable electrode finger pairs are arranged to face each other in the X direction.

In the acceleration sensor 1 of the present embodiment, the first movable electrode finger 22 and the fixed electrode finger 32 arranged adjacent to the −X side of the first movable electrode finger 22 constitute a first capacitor C1. Further, in the acceleration sensor 1 of the present embodiment, the second movable electrode finger 23 and the fixed electrode finger 32 arranged adjacent to the +X side of the second movable electrode finger 23 constitute a second capacitor C2.

When acceleration in the X-axis direction acts on the acceleration sensor 1, the first movable electrode finger 22 and the second movable electrode finger 23, which are connected to the movable electrode base 21, move relative to the fixed electrode 30 fixed to the substrate 10. The acceleration sensor 1 is configured to detect acceleration by taking out, from an electrode pad (not shown), a change in capacitance in each of the first capacitor C1 and the second capacitor C2 due to displacement of the movable electrode 20 in the X direction when acceleration acts as an electric signal.

The acceleration sensor 1 includes a first wiring layer 40 electrically connected to the first movable electrode finger 22 of the movable electrode 20, a second wiring layer 41 electrically connected to the second movable electrode finger 23 of the movable electrode 20, and a third wiring layer 42 electrically connected to the fixed electrode 30. The first wiring layer 40, the second wiring layer 41, and the third wiring layer 42 are made of a conductive silicon-containing material. The first wiring layer 40, the second wiring layer 41, and the third wiring layer 42 of the present embodiment are made of conductive polysilicon. The first wiring layer 40 of the present embodiment is an example of a wiring layer according to the present disclosure.

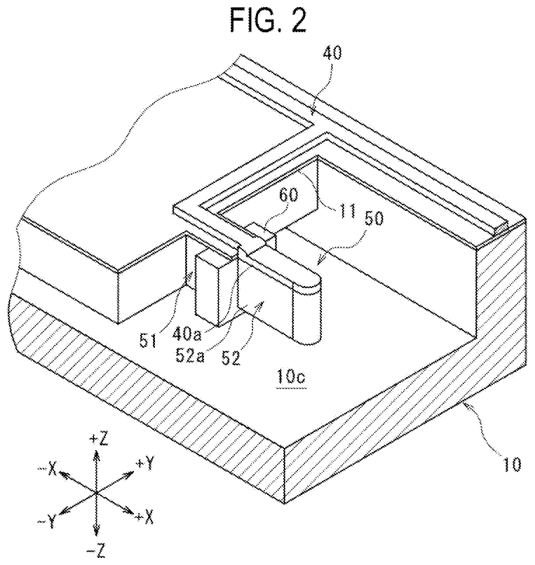

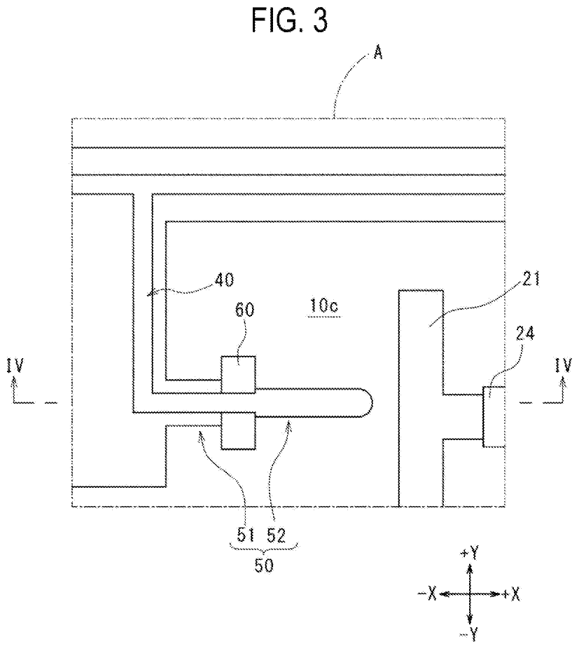

FIG. 2 is a perspective view of a vicinity of region A in FIG. 1. FIG. 3 is an enlarged plan view of region A in FIG. 1. FIG. 4 is a cross-sectional view taken along line IV-IV in FIG. 3.

The substrate 10 includes a silicon (Si) layer. The substrate 10 of the present embodiment consists of only a single silicon layer.

An insulating layer 11 is formed on the +Z side of the substrate 10. The insulating layer 11 is a silicon oxide (SiO₂) layer.

The substrate 10 of the present embodiment includes a bump stop 50 for restricting the movement of the movable electrode base 21 in the X-axis direction. The bump stop 50 protrudes in the shape of a cantilever in the X-axis direction from the side surface of the substrate 10 extending in the Y direction and the Z direction.

The acceleration sensor 1 includes an isolation joint 60 that divides the bump stop 50 into a proximal end portion 51 and a distal end portion 52 in a plan view. The isolation joint 60 mechanically connects the proximal end portion 51 and the distal end portion 52 and electrically insulates them. The isolation joint 60 is made of silicon oxide (SiO₂).

The proximal end portion 51 is arranged on the −X side of the isolation joint 60. The proximal end portion 51 includes a silicon layer. At the proximal end portion 51, an insulating layer 11 is formed on the +Z side of the silicon layer. The proximal end portion 51 of the present embodiment is an example of a first portion according to the present disclosure.

The distal end portion 52 is arranged on the +X side of the isolation joint 60. The distal end portion 52 includes a silicon layer. At the distal end portion 52, the insulating layer 11 is not formed on the +Z side of the silicon layer. The distal end portion 52 of the present embodiment is an example of a second portion according to the present disclosure.

The first wiring layer 40 is formed on the bump stop 50. The first wiring layer 40 is electrically insulated from the silicon layer by the insulating layer 11 at the proximal end portion 51, and is electrically connected to the silicon layer by being formed to be in contact with the silicon layer at the distal end portion 52. The distal end portion 52 is electrically connected to the first movable electrode finger 22 (see FIG. 1) by the first wiring layer 40. The distal end portion 52 and the portion of the movable electrode base 21 that faces the distal end portion 52 in the X direction are connected to the same potential by the first wiring layer 40.

As shown in FIG. 3, the portion of the first wiring layer 40 arranged on the distal end portion 52 has the same or substantially the same shape and size as the distal end portion 52 in a plan view. In other words, the portion of the first wiring layer 40 arranged on the distal end portion 52 and the distal end portion 52 are arranged to overlap so that the outer contours thereof match in a plan view.

As shown in FIG. 2, the first wiring layer 40 has a side surface 40a aligned with a side surface 52a of the distal end portion 52. Specifically, the side surface 40a of the portion of the first wiring layer 40 arranged on the distal end portion 52 is aligned with the side surface of the silicon layer constituting the distal end portion 52. In the present embodiment, the side surface 40a of the portion of the first wiring layer 40 arranged on the distal end portion 52 over the entire circumference is aligned with the side surface 52a of the distal end portion 52. In the present embodiment, the side surface 40a of the first wiring layer 40 and the side surface 52a of the distal end portion 52 extend continuously in the Z direction. In other words, the portion of the first wiring layer 40 arranged on the distal end portion 52 and the distal end portion 52 are formed in a self-aligned manner.

The portion of the first wiring layer 40 arranged on the proximal end portion 51 is smaller than the proximal end portion 51 in a plan view. In other words, the proximal end portion 51 is formed to be larger than the portion of the first wiring layer 40 arranged on the proximal end portion 51.

### [Acceleration Sensor Manufacturing Method]

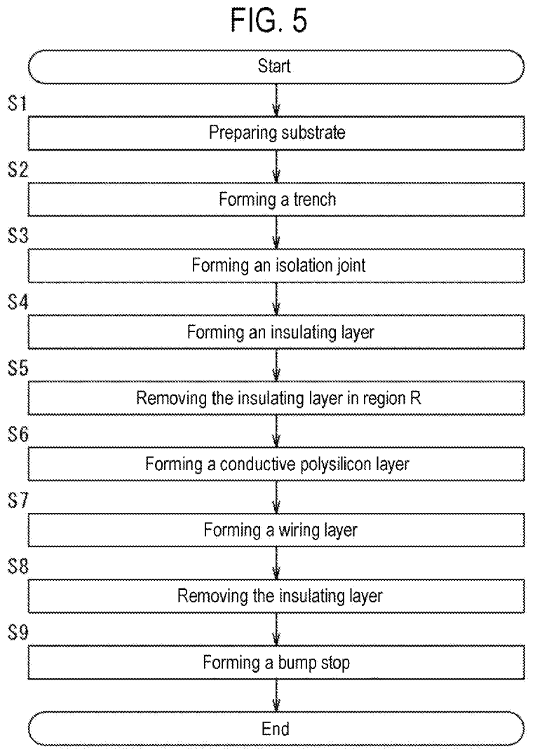

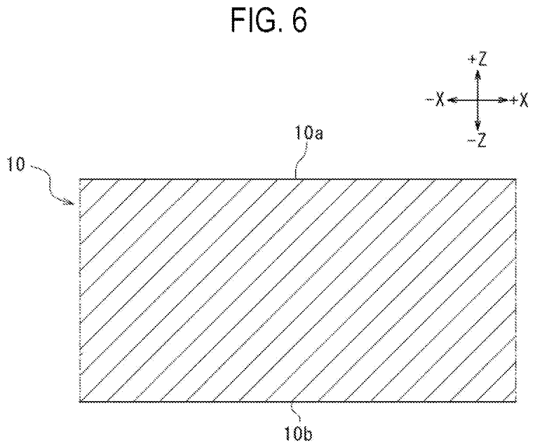

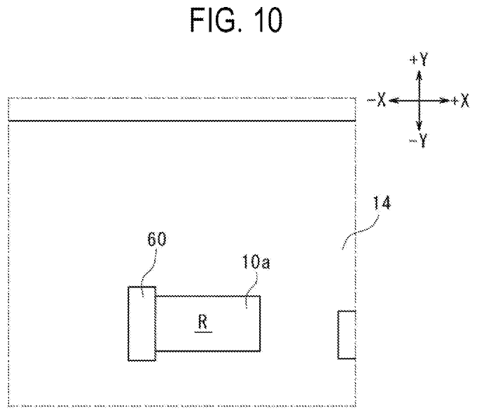

A method of manufacturing the acceleration sensor 1, particularly a method of manufacturing the structure around the bump stop 50, will be described with reference to FIGS. 5 to 15. FIG. 5 is a flowchart for explaining the method of manufacturing the acceleration sensor 1 according to the present embodiment. FIGS. 6 to 15 are diagrams for explaining the method of manufacturing the acceleration sensor 1 according to the present embodiment. FIGS. 6 to 9, 11, and 12 show cross-sectional views similar to FIG. 4, and FIGS. 10 and 13 to 15 show plan views similar to FIG. 3.

In step S1, as shown in FIG. 6, a substrate 10 including a silicon (Si) layer is prepared. The substrate 10 of the present embodiment consists of only a single silicon layer. The substrate 10 has a first main surface 10a located on the +Z side and a second main surface 10b located on the −Z side and opposite to the first main surface 10a.

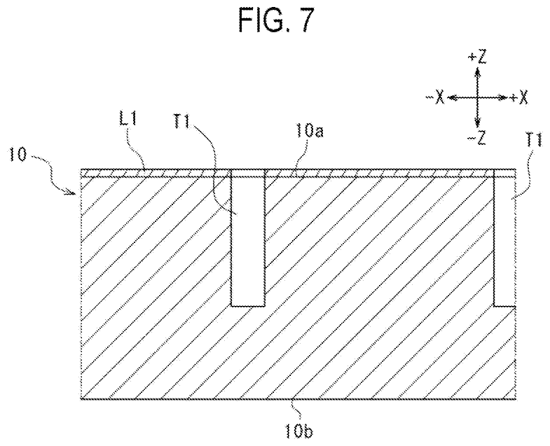

Next, in step S2, as shown in FIG. 7, a first trench T1 extending from the first main surface 10a of the substrate 10 toward the second main surface 10b is formed. Specifically, a first silicon oxide (SiO₂) layer L1 is formed on the first main surface 10a of the substrate 10 to expose a position corresponding to the isolation joint 60 (see FIG. 3). In FIG. 7, the first main surface 10a is also exposed at a position corresponding to the movable electrode isolation joint 24 (see FIG. 3). Next, a first trench T1 is formed by etching the substrate from the first main surface 10a toward the −Z side by anisotropic etching using the first silicon oxide layer L1 as a hard mask.

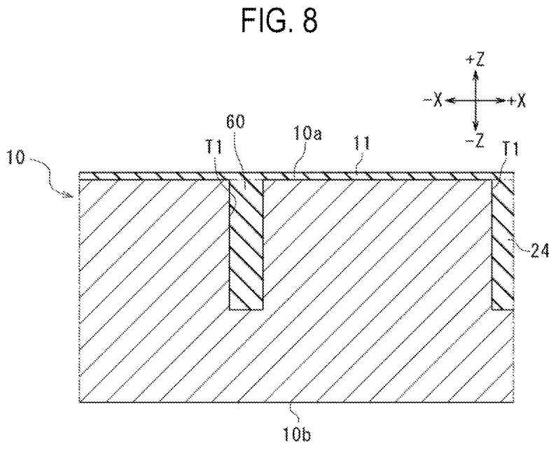

Next, in step S3, as shown in FIG. 8, an isolation joint 60 is formed by thermally oxidizing the wall surface of the first trench T1. Further, in step S4, an insulating layer 11 is formed on the first main surface 10a of the substrate 10. In the present embodiment, the formation of the isolation joint 60 in step S3 and the formation of the insulating layer 11 in step S4 are performed in the same process. Specifically, by thermally oxidizing the substrate 10 from the +Z side after removing the first silicon oxide layer L1 (see FIG. 7) from the substrate 10, a thermal oxide film made of thermally oxidized silicon is formed on the inner wall surface of the first trench T1 and the first main surface 10a. The thermal oxide film formed on the inner wall surface of the first trench T1 fills the inside of the first trench T1 and grows in the −Z direction to form the isolation joint 60. Further, the insulating layer 11 is constituted by the thermal oxide film formed on the first main surface 10a.

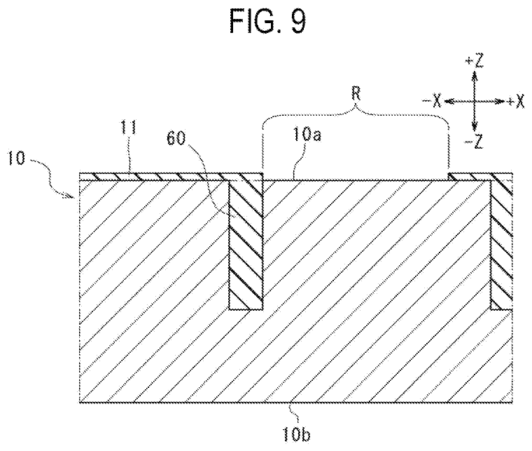

Next, in step S5, as shown in FIGS. 9 and 10, the portion of the insulating layer 11 formed on the first major surface 10a of the substrate 10, which is located in a region R adjacent to the isolation joint 60 in a plan view, is removed to expose the first major surface 10a. The region R is located more on the +X side than the isolation joint 60. The region R is larger than the distal end portion 52 (see FIG. 3) of the bump stop 50 in a plan view.

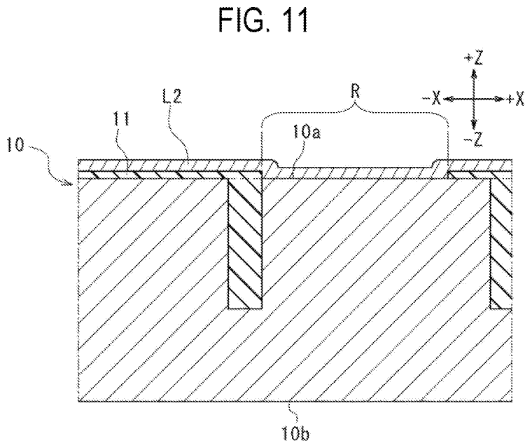

Next, in step S6, as shown in FIG. 11, a conductive polysilicon layer L2 is formed on the +Z side of the first main surface 10a of the substrate 10. The conductive polysilicon layer L2 is formed in the region R in contact with the silicon layer of the substrate 10.

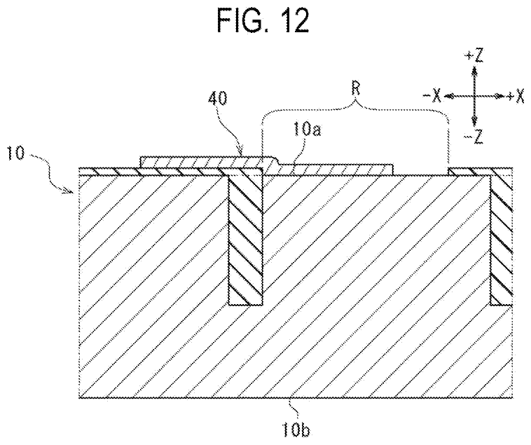

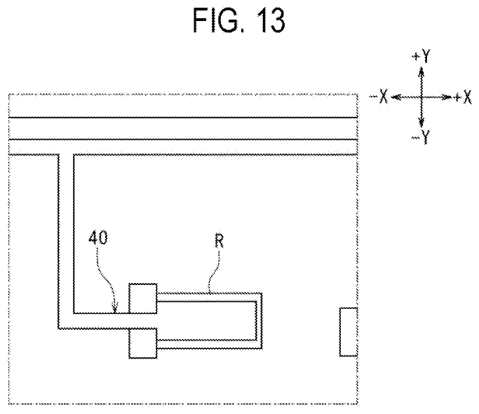

Next, in step S7, as shown in FIGS. 12 and 13, the conductive polysilicon layer L2 (see FIG. 11) is partially removed by being etched in a predetermined pattern. As a result, a first wiring layer 40 is formed on the first main surface 10a of the substrate 10. In step S7, the remaining conductive polysilicon layer L2 constitutes the first wiring layer 40. At this time, the first wiring layer 40 is formed in the region R in contact with the silicon layer of the substrate 10.

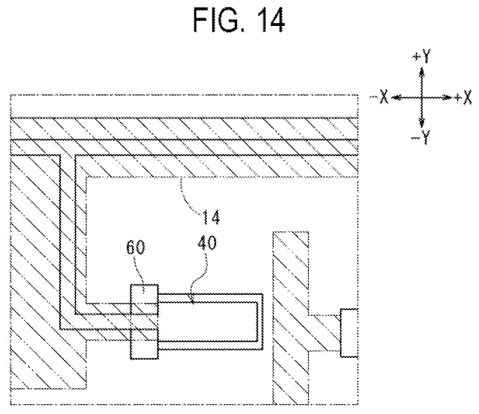

Next, in step S8, as shown in FIG. 14, the insulating layer 11 formed on the first main surface 10a of the substrate 10 is partially removed by being etched in a predetermined pattern. In FIG. 14, the remaining region of the insulating layer 11 is indicated by a two-dot chain line.

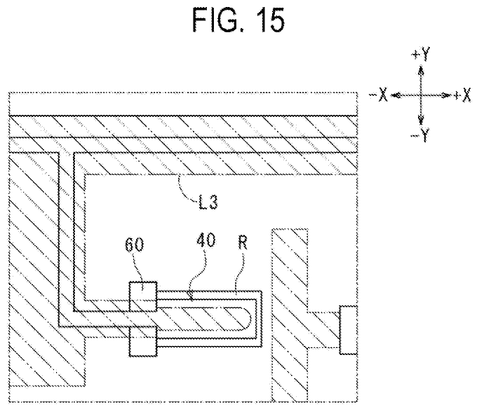

Next, in step S9, a bump stop 50 (see FIG. 3) is formed. Specifically, a second silicon oxide layer L3 is formed on the first main surface 10a of the substrate 10 so as to correspond to the shape of the acceleration sensor 1. In FIG. 15, a portion where the second silicon oxide layer L3 is formed is indicated by a two-dot chain line. Next, a second trench (not shown) is formed by etching the substrate 10 from the +Z side to the −Z side by anisotropic etching using the second silicon oxide layer L3 as a hard mask. The second trench is formed in a portion where the second silicon oxide layer L3 is not formed. At this time, in the region R, the first wiring layer 40 and the silicon layer of the substrate 10 are etched using the same mask (second silicon oxide layer L3).

Thereafter, although not shown, the silicon layer of the substrate 10 located on the −Z side of the bump stop 50 is removed by removing the bottom portion of the second trench by isotropic etching. Thus, the bottom portions of the adjacent second trenches are connected to each other, so that a cavity 10c is formed and a bump stop 50 is formed so as to be spaced apart from the bottom surface of the cavity 10c toward the +Z side.

According to the acceleration sensor 1 of the present embodiment, the following effects may be obtained.

(1) An acceleration sensor 1 includes: a substrate 10 including a silicon layer; an isolation joint 60 configured to divide the substrate 10 into a proximal end portion 51 including an insulating layer 11 formed on the silicon layer and a distal end portion 52 including the silicon layer in a plan view, and configured to electrically insulate the proximal end portion 51 and the distal end portion 52 while mechanically connecting the proximal end portion 51 and the distal end portion 52; and a first wiring layer 40 arranged on the substrate 10. The first wiring layer 40 is electrically insulated from the silicon layer by the insulating layer 11 at the proximal end portion 51 and electrically connected to the silicon layer by being formed to be in contact with the silicon layer at the distal end portion 52.

According to this configuration, the first wiring layer 40 is formed to be in contact with the silicon layer at the distal end portion 52 and is electrically connected to the silicon layer. Therefore, unlike the case where the insulating layer is arranged between the first wiring layer 40 and the silicon layer at the distal end portion 52 and electrically connected to the silicon layer through a via provided in the insulating layer, there is no need to take into account the misalignment with the insulating layer in the patterning when forming the distal end portion 52. Thus, unlike the case where the insulating layer is arranged between the first wiring layer 40 and the silicon layer at the distal end portion 52, there is no need to form the distal end portion 52 at a size larger than necessary. As a result, it is possible to suppress the distal end portion 52 from increasing in size, and therefore it is possible to suppress the acceleration sensor 1 from increasing in size.

(2) The first wiring layer 40 is made of a conductive silicon-containing material.

According to this configuration, at the distal end portion 52, the silicon layer and the first wiring layer 40 made of a silicon-containing material can be formed in the same etching process. For example, if the silicon layer included in the distal end portion 52 and the first wiring layer 40 are etched using the same mask, it is possible to form the distal end portion 52 and the first wiring layer 40 with a same size in a plan view. As a result, it is not necessary to form the distal end portion 52 with a size larger than necessary. Since it is possible to suppress the distal end portion 52 from increasing in size, it is possible to suppress the entire acceleration sensor 1 from increasing in size.

(3) The first wiring layer 40 has a side surface 40a aligned with a side surface 52a of the distal end portion 52.

According to this configuration, the portion of the first wiring layer 40 arranged on the distal end portion 52 has the side surface 40a aligned with the side surface 52a of the distal end portion 52. That is, the distal end portion 52 is formed to have the same size as the first wiring layer 40 in a plan view, and is not formed with a size larger than necessary. As a result, since it is possible to suppress the distal end portion 52 from increasing in size, it is possible to suppress the entire acceleration sensor 1 from increasing in size.

(4) A movable electrode base 21 is movable relative to the substrate 10. The distal end portion 52 is configured to contact the movable electrode base 21 to restrict movement of the movable electrode base 21 when the movable electrode base 21 is moved by a predetermined amount of movement.

If acceleration acts on the movable electrode base 21, and the movable electrode 20 and the fixed electrode 30 come too close to each other, the movable electrode 20 may stick to the fixed electrode 30 due to an electrostatic force. According to this configuration, since the movement of the movable electrode base 21 is restricted by the distal end portion 52, when acceleration acts on the movable electrode base 21, it is possible to suppress the movable electrode 20 and the fixed electrode 30 from coming too close to each other. As a result, it is possible to suppress the movable electrode 20 from sticking to the fixed electrode 30 due to an electrostatic force.

(5) The distal end portion 52 and the portion of the movable electrode base 21 facing the distal end portion 52 are connected to the same potential.

According to this configuration, since the distal end portion 52 and the portion of the movable electrode base 21 facing the distal end portion 52 are connected to the same potential, a repulsive force acts on the distal end portion 52 and the portion of the movable electrode base 21 facing the distal end portion 52 so as to separate them from each other. As a result, it is possible to suppress the distal end portion 52 from sticking to the movable electrode base 21, and it is possible to suppress the movable electrode 20 from sticking to the fixed electrode 30 due to an electrostatic force.

According to the method of manufacturing the acceleration sensor 1 according to the present embodiment, the following effects may be obtained.

(6) A method of manufacturing an acceleration sensor 1 according to the present embodiment includes: preparing a substrate 10 including a silicon layer and having a first main surface 10a as an outer surface of the silicon layer and a second main surface 10b opposite to the first main surface 10a; forming a first trench T1 extending from the first main surface 10a toward the second main surface 10b of the substrate 10; forming an isolation joint 60 by thermally oxidizing a wall surface of the first trench T1; forming an insulating layer 11 on the first main surface 10a; removing the insulating layer 11 in a region R adjacent to the isolation joint 60 in a plan view to expose the first main surface 10a; forming a first wiring layer 40 made of a conductive silicon-containing material on the first main surface 10a of the substrate 10, the first wiring layer 40 being formed to be in contact with the silicon layer in the region R; and etching the first wiring layer 40 and the silicon layer by using a same mask in the region R.

According to the manufacturing method, since the first wiring layer 40 and the silicon layer are etched using the same mask in the region R, the first wiring layer 40 and the silicon layer can be formed in the region R to have the same shape and size in a plan view. As a result, in the region R adjacent to the isolation joint 60, there is no need to form the silicon layer for supporting the first wiring layer 40 with a size larger than necessary. As a result, it is possible to suppress the acceleration sensor 1 from increasing in size.

### Other Embodiments

The MEMS device according to the present disclosure may be configured as follows.

In the above-described embodiment, the case has been described in which the substrate consists of only a silicon layer. However, the substrate according to the present disclosure may include another layer such as a silicon oxide (SiO₂) layer or a silicon carbide (SiC) layer in addition to the silicon layer. For example, the substrate according to the present disclosure may be an SOI (Silicon-On-Insulator) substrate.

In the above-described embodiment, the first wiring layer 40, the second wiring layer 41, and the third wiring layer 42 are made of conductive polysilicon. However, they may be made of metal.

In the above-described embodiment, the case has been described in which the present disclosure is applied to the bump stop. However, the present disclosure may be applied to a connection portion between the wiring layer and the movable electrode or a connection portion between the wiring layer and the fixed electrode.

### [Supplementary Notes]

Supplementary notes will be provided for the present disclosure in which specific configuration examples are shown in the above-described embodiments.

A MEMS device and a method of manufacturing a MEMS device according to the present disclosure provide the following aspects.

### [Aspect 1]

A MEMS device, comprising:
a substrate including a silicon layer;
an isolation joint configured to divide the substrate into a first portion including an insulating layer formed on the silicon layer and a second portion including the silicon layer in a plan view, and configured to electrically insulate the first portion and the second portion while mechanically connecting the first portion and the second portion; and a wiring layer arranged on the substrate, wherein the wiring layer is electrically insulated from the silicon layer by the insulating layer at the first portion and electrically connected to the silicon layer by being formed to be in contact with the silicon layer at the second portion.

### [Aspect 2]

The MEMS device of Aspect 1, wherein the wiring layer is made of a conductive silicon-containing material.

### [Aspect 3]

The MEMS device of Aspect 1 or 2, wherein the wiring layer has a side surface aligned with a side surface of the second portion.

### [Aspect 4]

The MEMS device of any one of Aspects 1 to 3, further comprising:
a movable portion which is movable relative to the substrate,
wherein the second portion is configured to contact the movable portion to restrict movement of the movable portion when the movable portion is moved by a predetermined amount of movement.

### [Aspect 5]

The MEMS device of Aspect 4, wherein the second portion and a portion of the movable portion facing the second portion are connected to a same potential.

### [Aspect 6]

A method of manufacturing a MEMS device, comprising:
preparing a substrate including a silicon layer and having a first main surface as an outer surface of the silicon layer and a second main surface opposite to the first main surface;
forming a trench extending from the first main surface toward the second main surface of the substrate;
forming an isolation joint by thermally oxidizing a wall surface of the trench;
forming an insulating layer on the first main surface;
removing the insulating layer in a region adjacent to the isolation joint in a plan view to expose the first main surface;
forming a wiring layer made of a conductive silicon-containing material on the first main surface of the substrate, the wiring layer being formed to be in contact with the silicon layer in the region; and
etching the wiring layer and the silicon layer by using a same mask in the region.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A MEMS device, comprising:
a substrate including a silicon layer;
an isolation joint configured to divide the substrate into a first portion including an insulating layer formed on the silicon layer and a second portion including the silicon layer in a plan view, and configured to electrically insulate the first portion and the second portion while mechanically connecting the first portion and the second portion; and
a wiring layer arranged on the substrate,
wherein the wiring layer is electrically insulated from the silicon layer by the insulating layer at the first portion and electrically connected to the silicon layer by being formed to be in contact with the silicon layer at the second portion.

2. The MEMS device of claim 1, wherein the wiring layer is made of a conductive silicon-containing material.

3. The MEMS device of claim 1, wherein the wiring layer has a side surface aligned with a side surface of the second portion.

4. The MEMS device of claim 1, further comprising:
a movable portion which is movable relative to the substrate,
wherein the second portion is configured to contact the movable portion to restrict movement of the movable portion when the movable portion is moved by a predetermined amount of movement.

5. The MEMS device of claim 4, wherein the second portion and a portion of the movable portion facing the second portion are connected to a same potential.

6. A method of manufacturing a MEMS device, comprising:
preparing a substrate including a silicon layer and having a first main surface as an outer surface of the silicon layer and a second main surface opposite to the first main surface;
forming a trench extending from the first main surface toward the second main surface of the substrate;
forming an isolation joint by thermally oxidizing a wall surface of the trench;
forming an insulating layer on the first main surface;
removing the insulating layer in a region adjacent to the isolation joint in a plan view to expose the first main surface;
forming a wiring layer made of a conductive silicon-containing material on the first main surface of the substrate, the wiring layer being formed to be in contact with the silicon layer in the region; and
etching the wiring layer and the silicon layer by using a same mask in the region.
